(19) United States
(12) Patent Application Publication
(10) Pub. No.: US 2024/0021749 A1
(43) Pub. Date: Jan. 18, 2024

(54) METHOD FOR MANUFACTURING LIGHT-EMITTING ELEMENT AND LIGHT-EMITTING ELEMENT

(71) Applicant: NICHIA CORPORATION, Anan-shi (JP)

(72) Inventor: Hiroki KONDO, Anan-shi (JP)

(73) Assignee: NICHIA CORPORATION, Anan-shi (JP)

(21) Appl. No.: 18/174,646

(22) Filed: Feb. 27, 2023

(30) Foreign Application Priority Data
Mar. 15, 2022 (JP) 2022-040395

(51) Int. Cl. H01L 33/00

(52) U.S. Cl. CPC H01L 33/005; H01L 33/0008; H01L 2933/0016

(57) ABSTRACT

A method for manufacturing a light-emitting element includes forming a first n-layer made of a nitride semiconductor layer above a first substrate using a first source gas including an Al source gas, a Ga source gas, and a Ge source gas. The method further includes forming a second n-layer made of a nitride semiconductor layer above the first n-layer using a second source gas including an Al source gas, a Ga source gas, and a Si source gas, exposing the second n-layer by removing the first substrate and the first n-layer, and forming an n-electrode on the second n-layer exposed in the exposing of the second n-layer.

### CROSS-REFERENCE TO RELATED APPLICATIONS

The present application claims priority under 35 U. S. C. § 119 to Japanese Patent Application No. 2022-040395, filed Mar. 15, 2022. The contents of this application are incorporated herein by reference in their entirety.

### TECHNICAL FIELD

The present invention relates to a method for manufacturing a light-emitting element and a light-emitting element.

### BACKGROUND ART

Silicon and germanium are used as impurities for creating an n-type gallium nitride semiconductor (for example, see JP 2007-59518 A).

### SUMMARY OF THE INVENTION

A method is provided for manufacturing a light-emitting element and a light-emitting element that can reduce forward voltage.

According to an aspect of the present invention, a method for manufacturing a light-emitting element includes forming a first n-layer made of a nitride semiconductor layer above a first substrate by using a first source gas including an Al source gas, a Ga source gas, and a Ge source gas, forming a second n-layer made of a nitride semiconductor layer above the first n-layer by using a second source gas including an Al source gas, a Ga source gas, and a Si source gas, forming an active layer made of a nitride semiconductor layer that emits ultraviolet light above the second n-layer, forming a p-layer made of a nitride semiconductor layer above the active layer, forming a p-electrode on the p-layer, exposing the second n-layer by removing the first substrate and the first n-layer, and forming an n-electrode on the second n-layer exposed in the step of exposing the second n-layer.

According to an aspect of the present invention, a method for manufacturing a light-emitting element includes forming a first n-layer made of a nitride semiconductor layer above a first substrate by using a first source gas including an Al source gas, a Ga source gas, and a Ge source gas, forming a second n-layer made of a nitride semiconductor layer above the first n-layer by using a second source gas including an Al source gas, a Ga source gas, and a Si source gas, forming an active layer made of a nitride semiconductor layer that emits ultraviolet light above the second n-layer, forming a p-layer made of a nitride semiconductor layer above the active layer, exposing a part of the second n-layer from the p-layer and the active layer by removing a part of the p-layer and a part of the active layer from a surface where the p-layer is exposed, forming an n-electrode on the part of the second n-layer, forming a p-electrode on the p-layer, and exposing the first n-layer by removing the first substrate.

According to an aspect of the present invention, a light-emitting element includes a semiconductor structure made of a nitride semiconductor layer including an n-layer, a p-layer, and an active layer that emits ultraviolet light and is disposed between the n-layer and the p-layer, an n-electrode disposed on the n-layer and electrically connected to the n-layer, and a p-electrode disposed on the p-layer and electrically connected to the p-layer. The n-layer contains Al, Ga, Si, and Ge, the n-layer includes a first surface where a plurality of protrusions are disposed, a second surface located opposite to the first surface and where the p-layer and the active layer are disposed, and a third surface located opposite to the first surface, exposed from the p-layer and the active layer, and where the n-electrode is connected, a Ge concentration in a portion proximate to the first surface of the n-layer is greater than a Ge concentration in a portion proximate to the second surface and the third surface of the p-layer, and a Si concentration in a portion proximate to the third surface of the n-layer is greater than a Si concentration in a portion proximate to the first surface of the n-layer.

### Advantageous Effects of Invention

According to the present invention, a method for manufacturing a light-emitting element and a light-emitting element that can reduce forward voltage can be provided.

### BRIEF DESCRIPTION OF DRAWINGS

FIG. 1 is a cross-sectional view for illustrating a process of a method for manufacturing a light-emitting element according to a first embodiment.

FIG. 2 is a cross-sectional view for illustrating a process of the method for manufacturing the light-emitting element according to the first embodiment.

FIG. 3 is a cross-sectional view for illustrating a process of the method for manufacturing the light-emitting element according to the first embodiment.

FIG. 4 is a cross-sectional view for illustrating a process of the method for manufacturing the light-emitting element according to the first embodiment.

FIG. 5 is a cross-sectional view for illustrating a process of the method for manufacturing the light-emitting element according to the first embodiment.

FIG. 6 is a cross-sectional view for illustrating a process of the method for manufacturing the light-emitting element according to the first embodiment.

FIG. 7 is a cross-sectional view for illustrating a process of the method for manufacturing the light-emitting element according to the first embodiment.

FIG. 8 is a cross-sectional view for illustrating a process of the method for manufacturing the light-emitting element according to the first embodiment.

FIG. 9 is a cross-sectional view for illustrating a process of the method for manufacturing the light-emitting element according to the first embodiment.

FIG. 10 is a cross-sectional view for illustrating a process of the method for manufacturing the light-emitting element according to the first embodiment.

FIG. 11 is a cross-sectional view for illustrating a process of the method for manufacturing the light-emitting element according to the first embodiment.

FIG. 12 is a cross-sectional view for illustrating a process of the method for manufacturing the light-emitting element according to the first embodiment.

FIG. 13 is a plan view of the light-emitting element according to the first embodiment.

FIG. 14 is a cross-sectional view for illustrating a process of a method for manufacturing a light-emitting element according to a second embodiment.

FIG. 15 is a cross-sectional view for illustrating a process of the method for manufacturing the light-emitting element according to the second embodiment.

FIG. 16 is a cross-sectional view for illustrating a process of the method for manufacturing the light-emitting element according to the second embodiment.

FIG. 17 is a cross-sectional view for illustrating a process of the method for manufacturing the light-emitting element according to the second embodiment.

FIG. 18 is a cross-sectional view for illustrating a process of the method for manufacturing the light-emitting element according to the second embodiment.

FIG. 19 is a cross-sectional view for illustrating a process of the method for manufacturing the light-emitting element according to the second embodiment.

FIG. 20 is a cross-sectional view for illustrating a process of the method for manufacturing the light-emitting element according to the second embodiment.

FIG. 21 is a plan view of the light-emitting element according to the second embodiment.

### DESCRIPTION OF EMBODIMENTS

Embodiments will be described below with reference to the drawings. In the drawings, the same constituent elements are denoted using the same reference characters. Note that the drawings are diagrams that schematically illustrate embodiments, and thus scales and intervals of members, positional relationships, and the like may be exaggerated, or some of the members may not be illustrated in the drawings. As a cross-sectional view, an end surface illustrating only a cut surface may be illustrated.

In the following description, components having substantially the same function may be denoted by the same reference characters and a description thereof may be omitted. Further, terms indicating a specific direction or position (“upper”, “lower”, and other terms including those terms) may be used. However, these terms are used merely to make it easy to understand relative directions or positions in the referenced drawing. As long as the relative direction or position is the same as that described in the referenced drawing using the term such as “upper” or “lower”, in drawings other than the drawings of the present disclosure, actual products, and the like, components may not be arranged in the same manner as in the referenced drawing. In the present description, “parallel” includes not only a case in which two straight lines, sides, surfaces, or the like do not intersect even if extended, but also a case in which angles formed by two straight lines, sides, surfaces, or the like intersect in a range of 10° or less. In the present specification, a positional relationship that expresses “above” includes a case in which an object is in contact and also a case in which an object is not in contact but located above.

### First Embodiment

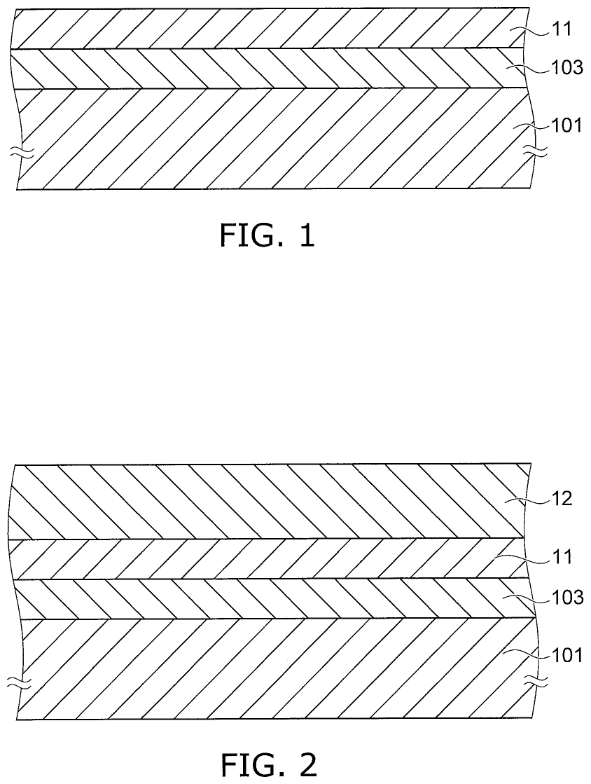

A method for manufacturing a light-emitting element according to a first embodiment will be described with reference to FIGS. 1 to 12.

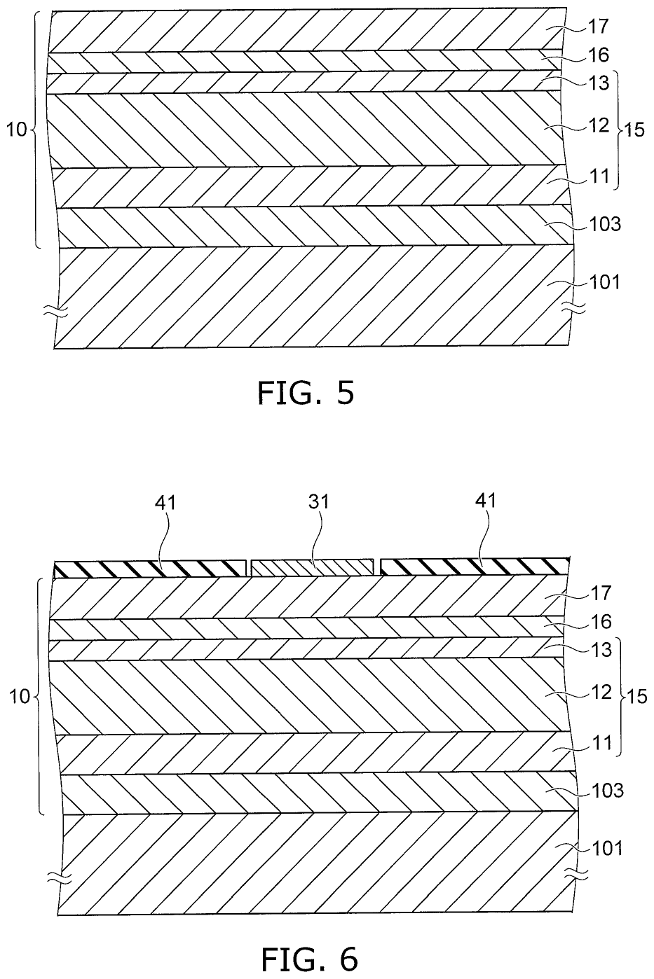

The method for manufacturing the light-emitting element according to the first embodiment includes a process of forming a semiconductor structure 10 above a first substrate 101 as illustrated in FIG. 5. The process of forming the semiconductor structure 10 includes a process of forming an n-layer 15, a process of forming an active layer 16, and a process of forming a p-layer 17. The n-layer 15, the active layer 16, and the p-layer 17 each are made of a nitride semiconductor. The nitride semiconductor includes a semiconductor containing all compositions having a chemical formula of InₓAl_{y}Ga_{1-x-y}N (0≤x≤1, 0≤y≤1, x+y≤1) provided that the composition ratios x and y are within the respective ranges. To form the semiconductor layers included in the semiconductor structure 10, for example, the metal organic chemical vapor deposition (MOCVD) method or the like can be used.

As illustrated in FIG. 1, the process of forming the n-layer 15 includes a process of forming a first n-layer 11 above the first substrate 101. The first n-layer 11 is preferably formed above the first substrate 101 through an underlayer 103. The first substrate 101 is a substrate for growing a nitride semiconductor layer. A sapphire substrate can be used as the first substrate 101, for example. An undoped gallium nitride (GaN) layer can be used as the underlayer 103, for example. The thickness of the underlayer 103 is, for example, in a range from 5 μm to 8 μm.

The first n-layer 11 is formed above the first substrate 101 by using a first source gas. The first source gas includes an aluminum (Al) source gas, a gallium (Ga) source gas, a germanium (Ge) source gas, and a nitrogen (N) source gas. As the Al source gas, a gas containing trimethylaluminum can be used, for example. As the Ga source gas, a gas containing trimethylgallium or triethylgallium can be used, for example. As the Ge source gas, a gas containing tetraethylgermanium can be used, for example. As the N source gas, a gas containing ammonia can be used, for example. The first n-layer 11 is an n-type AlGaN layer containing Ge as the n-type impurity. The Al composition ratio of the first n-layer 11 is in a range from 2% to 10%, for example. The Ge concentration of the first n-layer 11 is in a range from 1×10¹⁸ cm⁻³ to 1×10²⁰ cm⁻³, for example.

As illustrated in FIG. 2, the process of forming the n-layer 15 includes a process of forming a second n-layer 12 above the first n-layer 11. The second n-layer 12 can be formed by using a second source gas. The second source gas includes an Al source gas, a Ga source gas, a silicon (Si) source gas, and a N source gas. The Al source gas, Ga source gas, and N source gas in the second source gas can be the same as in the first source gas. As the Si source gas, a gas containing monosilane can be used, for example. The second n-layer 12 is an n-type AlGaN layer containing Si as the n-type impurity. The Al composition ratio of the second p-layer 12 is in a range from 2% to 10%, for example. The Si concentration of the second p-layer 12 is in a range from 1×10¹⁸ cm⁻³ to 1×10²⁰ cm⁻³, for example. The Si concentration of the second n-layer 12 is greater than the Si concentration of the first n-layer 11. The Ge concentration of the second n-layer 12 is less than the Ge concentration of the first n-layer 11. Note that the Si concentration represents the impurity concentration of the Si contained in the semiconductor layer. Also, the Ge concentration represents the impurity concentration of the Ge contained in the semiconductor layer.

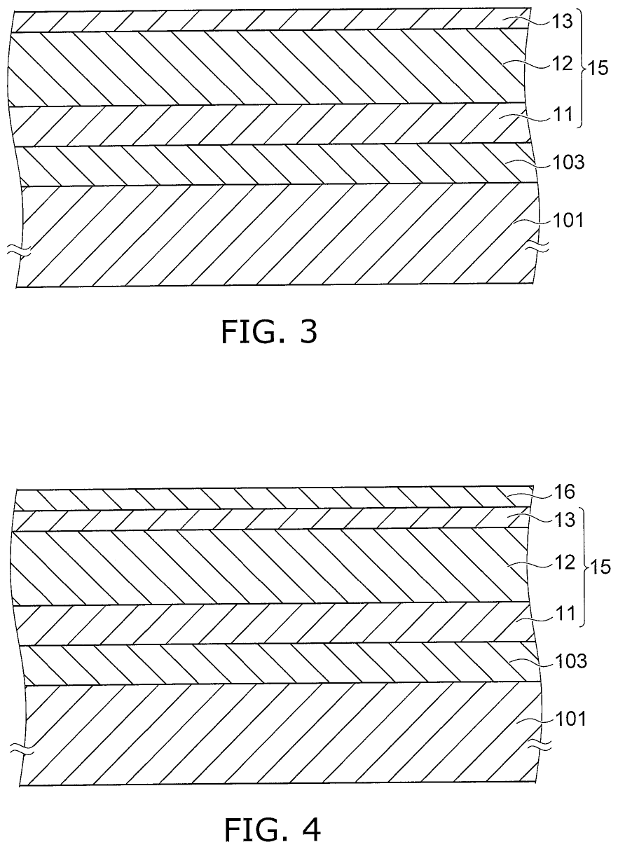

The active layer 16 is formed above the second n-layer 12. The active layer 16 is preferably formed above the second n-layer 12 through a third n-layer 13 illustrated in FIG. 3. In this case, the process of forming the n-layer 15 includes a process of forming the third p-layer 13 above the second n-layer 12 after the process of forming the second n-layer 12. The third n-layer 13 can be formed by using the same second source gas as that used to form the second n-layer 12. The third n-layer 13 is an n-type AlGaN layer containing Si as the n-type impurity. The Al composition ratio of the third n-layer 13 is in a range from 2% to 10%, for example.

The Si concentration of the third n-layer 13 is less than the Si concentration of the second n-layer 12. The Si concentration of the third n-layer 13 is less than the Ge concentration of the first n-layer 11. That is, the n-type impurity concentration of the third p-layer 13 is less than the n-type impurity concentration of the second n-layer 12 and the n-type impurity concentration of the first n-layer 11. The Si concentration of the third n-layer 13 is in a range from 1×10¹⁶ cm⁻³ to 1×10¹⁸ cm⁻³, for example.

In the process of forming the third n-layer 13, the third n-layer 13 is preferably formed thinner than the first n-layer 11 and the second n-layer 12. For example, in the process of forming the third n-layer 13, the third n-layer 13 is formed with a thickness in a range from 0.1 μm to 0.3 μm.

Because the third n-layer 13 has a less n-type impurity concentration than that of the second n-layer 12, the crystallizability and the flatness of the third n-layer 13 can be improved over that of the second n-layer 12. Thus, by forming the active layer 16 above the second p-layer 12 through the third n-layer 13, the crystallizability and the flatness of the active layer 16 can be improved.

As illustrated in FIG. 4, the active layer 16 is formed above the third n-layer 13. The active layer 16 emits ultraviolet light. For example, the light emission peak wavelength of the light from the active layer 16 is 400 nm or less, is specifically in a range from 210 nm to 400 nm, and is more specifically in a range from 300 nm to 400 nm.

As illustrated in FIG. 5, the p-layer 17 is formed above the active layer 16. The p-layer 17 includes a p-type AlGaN layer. The p-type AlGaN layer contains magnesium (Mg) as a p-type impurity, for example.

As illustrated in FIG. 6, the method for manufacturing the light-emitting element according to the first embodiment includes a process of forming a p-electrode 31 on the p-layer 17. The p-electrode 31 is electrically connected to the p-layer 17. Also, the method for manufacturing the light-emitting element according to the first embodiment includes a process of forming a first protective film 41 on the p-layer 17. The first protective film 41 is formed in a region on the p-layer 17 where the p-electrode 31 is not formed. The first protective film 41 is a film with insulating properties. A silicon oxide film or a silicon nitride film can be used as the first protective film 41, for example.

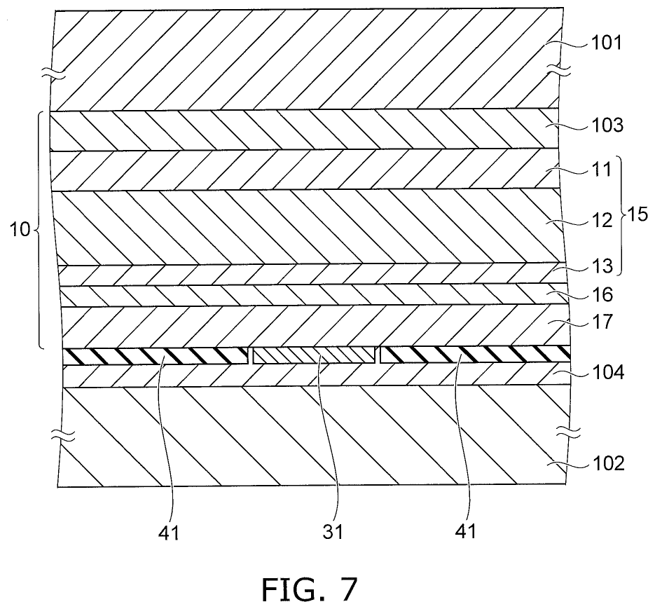

As illustrated in FIG. 7, the method for manufacturing the light-emitting element according to the first embodiment includes a process of forming the p-electrode 31 and the first protective film 41 and thereafter a process of disposing a second substrate 102 at a position proximate to the p-layer 17 and joining the p-electrode 31 and the second substrate 102. A silicon substrate can be used as the second substrate 102, for example. The p-electrode 31 is joined to the second substrate 102 through a joint member 104. The first protective film 41 is also joined to the second substrate 102 through the joint member 104. A metal member containing tin can be used as the joint member 104, for example.

The method for manufacturing the light-emitting element according to the first embodiment includes a process of joining the p-electrode 31 and the second substrate 102 and thereafter a process of removing the first substrate 101 and the first n-layer 11 and exposing the second n-layer 12.

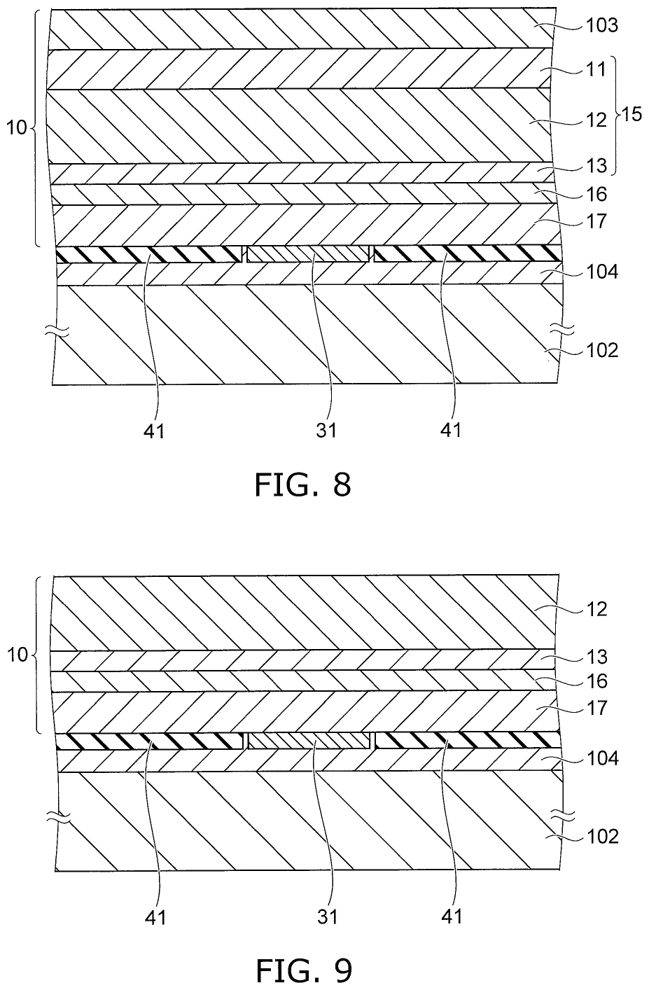

In a case in which a sapphire substrate is used as the first substrate 101, the first substrate 101 can be removed by the laser lift-off method. In a case in which the underlayer 103 has been formed, by removing the first substrate 101, the underlayer 103 is exposed as illustrated in FIG. 8. Thereafter, the underlayer 103 and the first n-layer 11 are removed. The underlayer 103 and the first n-layer 11 can be removed by dry etching, for example. The dry etching used can be Reactive Ion Etching (RIE), for example.

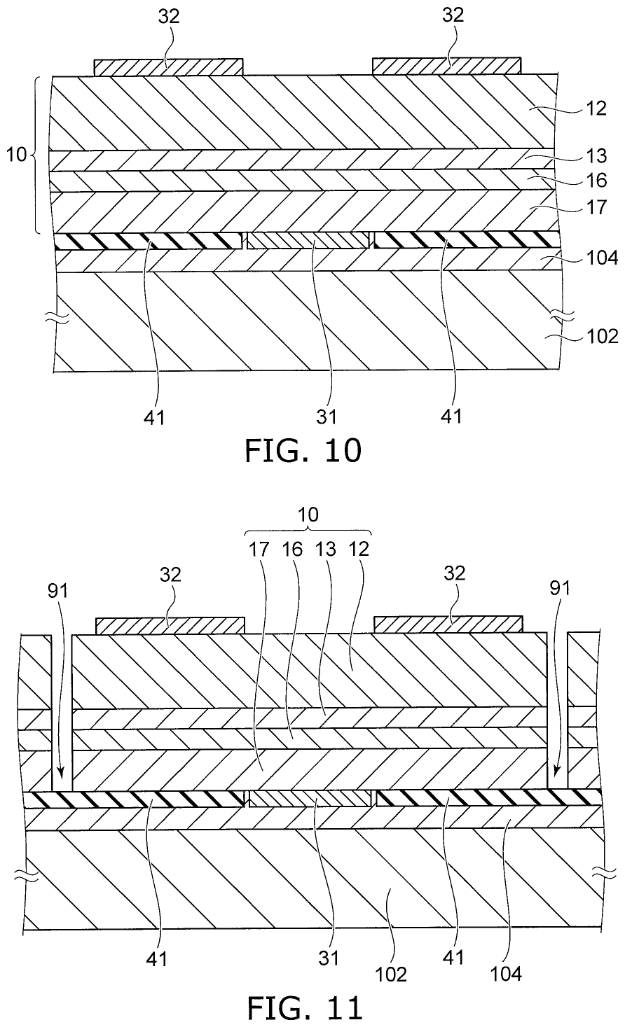

By removing the underlayer 103 and the first n-layer 11, the second n-layer 12 is exposed as illustrated in FIG. 9. In the process of exposing the second n-layer 12, a part of the second n-layer 12 may be removed. The method for manufacturing the light-emitting element according to the first embodiment includes, as illustrated in FIG. 10, a process of forming an n-electrode 32 on the second n-layer 12 exposed in the process of exposing the second n-layer 12. The n-electrode 32 is formed on the second n-layer 12 in a region located above the first protective film 41. The n-electrode 32 is not formed on the second n-layer 12 in a region located above the p-electrode 31. The n-electrode 32 is electrically connected to the second p-layer 12. Note that, before the process of forming the n-electrode 32, a process of roughening a portion of the upper surface of the second n-layer 12 where the n-electrode 32 is not formed may be included. For the method of roughening the second n-layer 12, a Chemical Mechanical Polishing (CMP) method or the like can be used, for example.

The method for manufacturing the light-emitting element according to the first embodiment includes a process of forming a groove 91 in the semiconductor structure 10 and separating the semiconductor structure 10 into a plurality of element portions after the n-electrode 32 is formed as illustrated in FIG. 11.

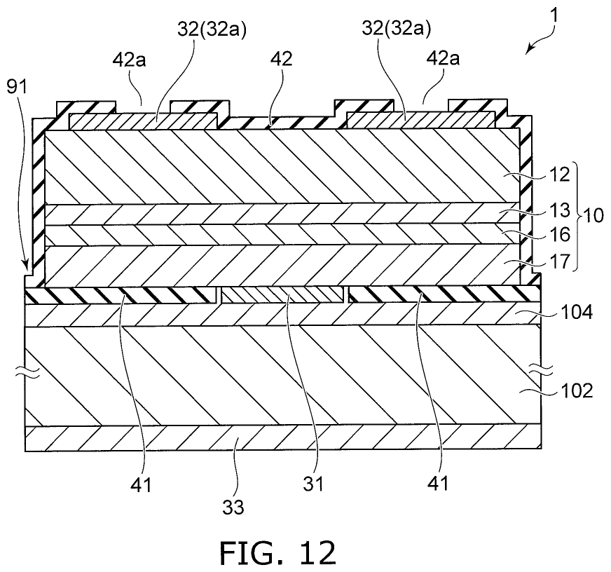

The method for manufacturing the light-emitting element according to the first embodiment includes a process of forming a second protective film 42 as illustrated in FIG. 12. The second protective film 42 is a film with insulating properties. SiN, SiO₂, or the like can be used for the second protective film 42, for example. The second protective film 42 covers a lateral surface of the semiconductor structure 10 demarcating the groove 91, the upper surface of the second n-layer 12, and the n-electrode 32. An opening portion 42a is formed in a part of the second protective film 42 that covers the upper surface of the n-electrode 32. A part of the n-electrode 32 is exposed from the second protective film 42 via the opening portion 42a. Also, the method for manufacturing the light-emitting element according to the first embodiment includes a process of forming a back surface electrode 33 on the back surface of the second substrate 102. The back surface electrode 33 is electrically connected to the p-electrode 31 via the second substrate 102 and the joint member 104. Thereafter, a light-emitting element 1 illustrated in FIG. 12 is obtained by cutting the first protective film 41, the joint member 104, the second substrate 102, and the back surface electrode 33 at the position of the groove 91.

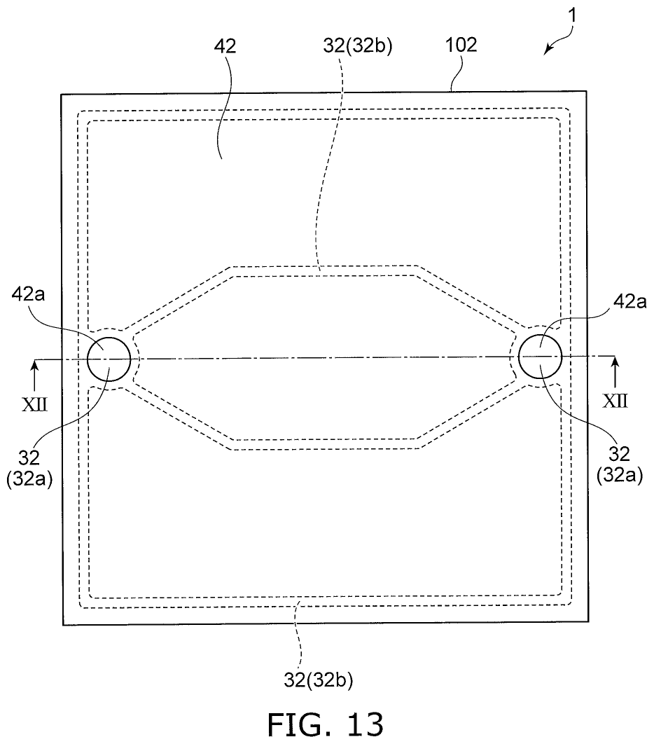

FIG. 13 is a plan view of the light-emitting element 1 according to the first embodiment. FIG. 12 is a cross-sectional view taken along line XII-XII in FIG. 13.

As illustrated in FIG. 13, the n-electrode 32 includes a pad portion 32a and an extending portion 32b. The n-electrode 32 includes, for example, two pad portions 32a. A part of the pad portion 32a is exposed from the second protective film 42 at the opening portion 42a. A plurality of the extending portions 32b extend from the pad portion 32a. For example, in a plan view, one of the extending portions 32b extends along the outer edge of the light-emitting element 1. Also, two extending portions 32b each connect between the two pad portions 32a.

The light-emitting element 1 is mounted on a wiring substrate that includes a wiring portion. The back surface electrode 33 is joined to the wiring portion of the wiring substrate and is electrically connected to the wiring portion. A wire electrically connected to the wiring portion of the wiring substrate is joined to the pad portion 32a of the n-electrode 32 exposed from the second protective film 42.

The difference between the atomic radius of Ge and the atomic radius of Ga is less than the difference between the atomic radius of Si and the atomic radius of Ga. Here, when a GaN layer containing impurities is formed by using a Ge source gas or an Si source gas, for example, the Ge or Si impurities replace the Ga in the GaN layer. This may cause point defects. It is presumed that the occurrence rate of point defects can be reduced by reducing the difference between the atomic radius of Ga and the atomic radius of Ge or Si that replace Ga. From this, it is thought that the first n-layer 11 containing Ge at a greater concentration than the second n-layer 12 is less likely to produce point defects than the second n-layer 12 and thus has good crystallizability. Thus, it is easier to improve the crystallizability of the first p-layer 11 than to improve the crystallizability of the second n-layer 12. According to the first embodiment, the first n-layer 11 is formed above the first substrate 101 and the second n-layer 12 is formed above the first n-layer 11. This makes it easy to also improve the crystallizability of the second n-layer 12. On the other hand, the second n-layer 12 containing Si at a greater concentration than the first n-layer 11 can have less sheet resistance of the second n-layer 12 itself and less contact resistance with the n-electrode 32 than those of the first n-layer 11. According to the first embodiment, the n-electrode 32 for electrically connecting to the p-layer 15 is connected to the second n-layer 12. That is, according to the first embodiment, the crystallizability of the n-layer 15 can be improved and the resistance of the n-layer 15 at the connection portion with the n-electrode 32 can be reduced. Accordingly, the forward voltage can be reduced.

The second n-layer 12 that comes into contact with the n-electrode 32 functions as a diffusion layer that diffuses the current supplied from the n-electrode 32. Thus, to facilitate diffusion of the current in the second n-layer 12, in the process of forming the second n-layer 12, the second n-layer 12 is preferably formed thicker than the first n-layer 11. In a case in which a GaN layer is formed as the second n-layer 12 on a sapphire substrate, the proportion of the thickness of the GaN layer to the thickness of the n-layer 15 tends to be greater and wafer warping tends to be greater. In contrast, by forming an AlGaN layer as the second p-layer 12 on a sapphire substrate, wafer warping can be reduced compared to the case where the GaN layer is formed as the second n-layer 12.

Because the first n-layer 11 is removed, the first n-layer 11 is made thinner than the second n-layer 12 to facilitate this removal of the first n-layer 11. For example, in the process of forming the first n-layer 11, the first n-layer 11 is formed with a thickness in a range from 0.2 μm to 1.2 μm. For example, in the process of forming the second n-layer 12, the second p-layer 12 is formed with a thickness in a range from 1 μm to 3 μm.

In the process of removing the first n-layer 11, a part of the first n-layer 11 may be left in a region on the second n-layer 12 where the n-electrode 32 is not disposed, instead of removing all of the first n-layer 11.

### Second Embodiment

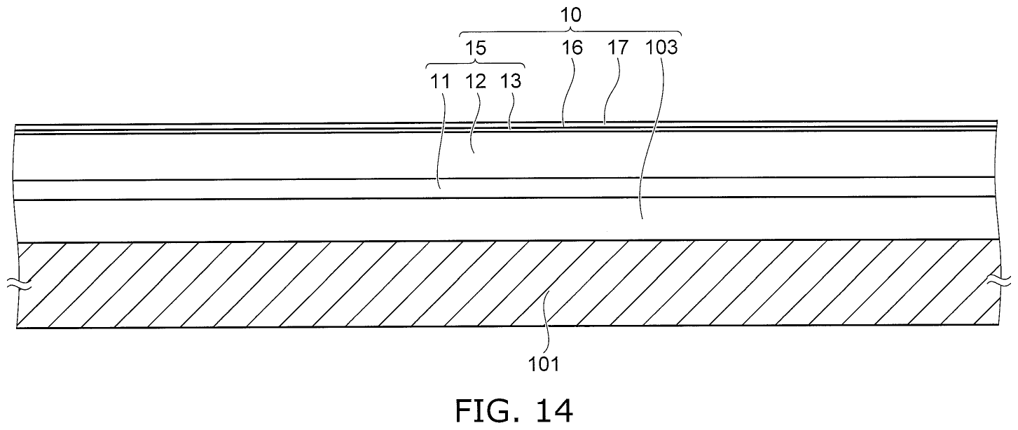

A method for manufacturing a light-emitting element according to a second embodiment will be described with reference to FIGS. 14 to 20.

In a similar manner to the first embodiment, the method for manufacturing a light-emitting element according to the second embodiment also includes a process of forming the semiconductor structure 10 above the first substrate 101 as illustrated in FIG. 14. The process of forming the semiconductor structure 10 includes a process of forming the n-layer 15, a process of forming the active layer 16, and a process of forming the p-layer 17. The process of forming the n-layer 15 includes a process of forming the first n-layer 11 above the first substrate 101 through the underlayer 103 and a process of forming the second n-layer 12 above the first n-layer 11. Also, the process of forming the n-layer 15 can include a process of forming the third n-layer 13 above the second n-layer 12.

Also, in the second embodiment, the crystallizability of the first n-layer 11 containing Ge at a greater concentration than the second n-layer 12 is easier to improve than the crystallizability of the second n-layer 12. Thus, the first n-layer 11 is formed above the first substrate 101 and the second n-layer 12 is formed above the first n-layer 11. This makes it possible to also improve the crystallizability of the second n-layer 12.

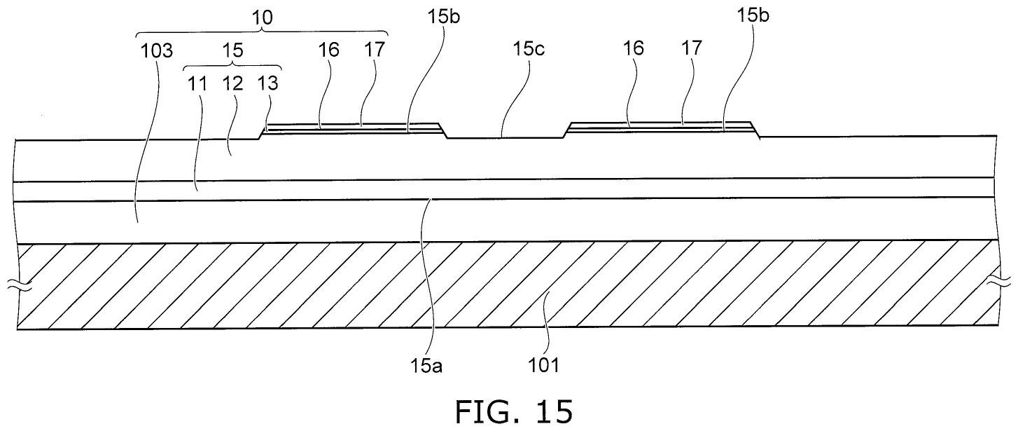

The method for manufacturing the light-emitting element according to the second embodiment includes a process of removing a part of the p-layer 17 and a part of the active layer 16 from a surface where the p-layer 17 is exposed and exposing a part of the second p-layer 12 from the p-layer 17 and the active layer 16 after the semiconductor structure 10 is formed above the first substrate 101, as illustrated in FIG. 15. In a case in which the third p-layer 13 has been formed, a part of the p-layer 17, a part of the active layer 16, and a part of the third n-layer 13 are removed from a surface where the p-layer 17 is exposed, and a part of the second n-layer 12 is exposed from the p-layer 17, the active layer 16, and the third n-layer 13. For example, a part of the p-layer 17, a part of the active layer 16, and a part of the third n-layer 13 can be removed by RIE or the like.

The n-layer 15 includes a first surface 15a located proximate to the first substrate 101, a second surface 15b located opposite to the first surface 15a and where the p-layer 17 and the active layer 16 are disposed, and a third surface 15c located opposite to the first surface 15a and exposed from the p-layer 17 and the active layer 16. In FIG. 15, the first surface 15a corresponds to the lower surface of the first n-layer 11, the second surface 15b corresponds to the upper surface of the third n-layer 13, and the third surface 15c corresponds to the part of the second n-layer 12 exposed from the p-layer 17, the active layer 16, and the third n-layer 13.

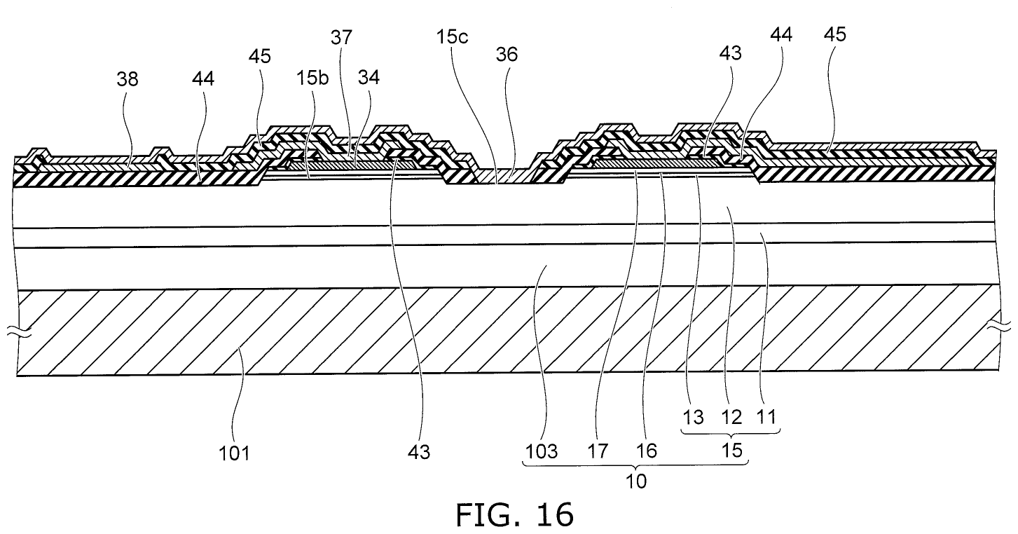

After a part (the third surface 15c) of the second n-layer 12 is exposed, as illustrated in FIG. 16, a reflective electrode 34 is formed on the p-layer 17. The reflective electrode 34 preferably has high reflectivity with respect to the light emitted by the active layer 16. The reflective electrode 34 is a metal layer containing Ag, for example. Here, the expression “the reflective electrode 34 having high reflectance with respect to the light emitted by the active layer 16” means that the reflective electrode 34 has a reflectance of 70% or more and preferably 80% or more with respect to the wavelength of the light from the active layer 16.

After the reflective electrode 34 is formed, a first insulating film 43 is formed so as to cover the reflective electrode 34 and the upper surface of the p-layer 17. SiN, SiO₂, or the like can be used for the first insulating film 43, for example.

After the first insulating film 43 is formed, a second insulating film 44 is formed. The second insulating film 44 covers the first insulating film 43, the third surface 15c, the lateral surface of the p-layer 17, the lateral surface of the active layer 16, the lateral surface of the third n-layer 13, and the lateral surface of the second n-layer 12 below the third n-layer 13. SiN, SiO₂, or the like can be used for the second insulating film 44, for example.

After the second insulating film 44 is formed, a part of the first insulating film 43 and a part of the second insulating film 44 on the reflective electrode 34 are removed, and a first p-opening portion exposing the reflective electrode 34 is formed. After the first p-opening portion is formed, a p-electrode 37 is formed on the second insulating film 44 in the first p-opening portion. In the first p-opening portion, the p-electrode 37 comes into contact with the reflective electrode 34. The p-electrode 37 is electrically connected to the p-layer 17 through the reflective electrode 34. Also, a conductive member 38 is formed on the second insulating film 44. The p-electrode 37 and the conductive member 38 can be formed by using the same material and the same process. A metal layer containing Al and/or Cu can be used as the p-electrode 37 and the conductive member 38, for example.

After the p-electrode 37 and the conductive member 38 are formed, a third insulating film 45 is formed on the second insulating film 44 so as to cover the p-electrode 37 and the conductive member 38. SiN, SiO₂, or the like can be used for the third insulating film 45, for example.

After the third insulating film 45 is formed, a part of the second insulating film 44 and a part of the third insulating film 45 on the third surface 15c are removed, and a first n-opening portion exposing the third surface 15c is formed. Also, after the third insulating film 45 is formed, a part of the third insulating film 45 on the conductive member 38 is removed, and a second n-opening portion is formed.

After the first n-opening portion and the second n-opening portion are formed, an n-electrode 36 is formed on the third insulating film 45, in the first n-opening portion, and in the second n-opening portion. In the first n-opening portion, the n-electrode 36 comes into contact with the third surface 15c, and thus the n-electrode 36 and the n-layer 15 are electrically connected. In the second n-opening portion, the n-electrode 36 comes into contact with the conductive member 38. A metal layer containing Al and/or Cu can be used as the n-electrode 36, for example.

The second n-layer 12 containing Si at a greater concentration than the first n-layer 11 can have lower resistivity than that of the first n-layer 11. According to the second embodiment, the n-electrode 36 for electrically connecting to the n-layer 15 is connected to the second n-layer 12. That is, according to the second embodiment, as described above, the crystallizability of the n-layer 15 can be improved and the resistance of the n-layer 15 at the connection portion with the n-electrode 36 can be reduced. Accordingly, the forward voltage can be reduced.

The second n-layer 12 that comes into contact with the n-electrode 36 functions as a diffusion layer that diffuses the current supplied from the n-electrode 36. Thus, to facilitate diffusion of the current in the second n-layer 12, in the process of forming the second n-layer 12, the second n-layer 12 is preferably formed thicker than the first n-layer 11.

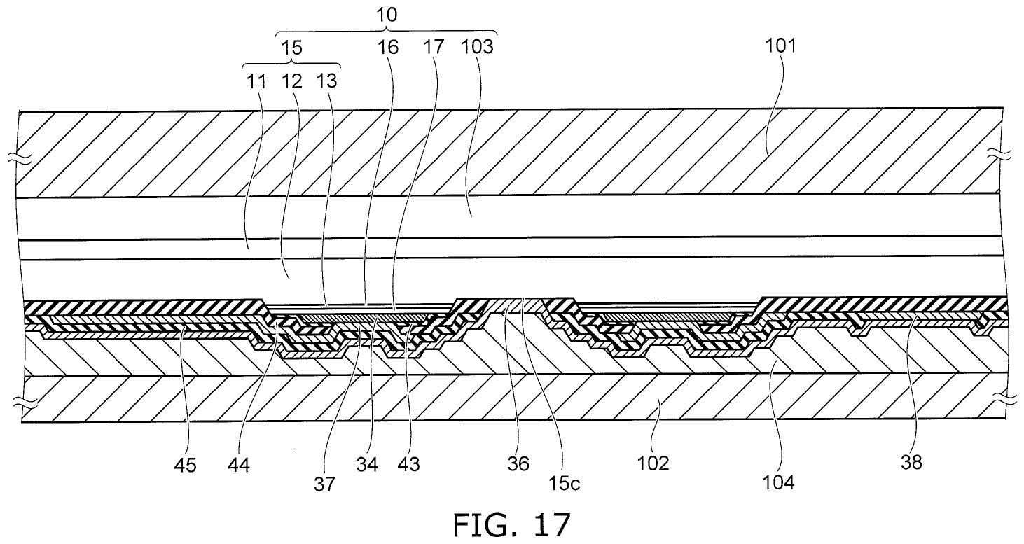

The method for manufacturing the light-emitting element according to the second embodiment includes a process of forming the p-electrode 37 and a process of forming the n-electrode 36 and thereafter a process of disposing the second substrate 102 at a position proximate to the n-electrode 36 and the p-electrode 37 of the semiconductor structure 10 as illustrated in FIG. 17. A silicon substrate can be used as the second substrate 102, for example. The n-electrode 36 is joined to the second substrate 102 through the joint member 104. A metal member containing tin can be used as the joint member 104, for example.

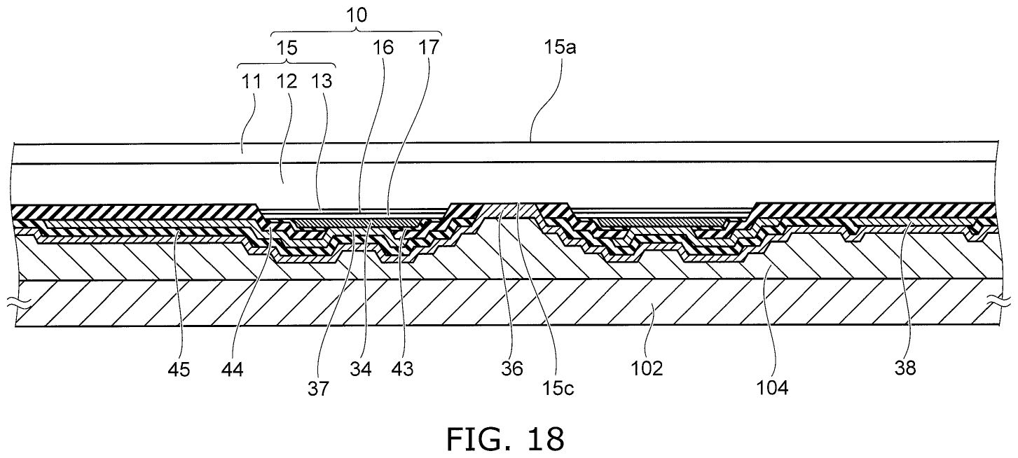

The method for manufacturing the light-emitting element according to the second embodiment includes a process of removing the first substrate 101 and exposing the first n-layer 11 after the process of disposing the second substrate 102. In a case in which a sapphire substrate is used as the first substrate 101, the first substrate 101 may be removed by the laser lift-off method, for example. In a case in which the underlayer 103 has been formed, the underlayer 103 is removed after the first substrate 101 is removed. By removing the first substrate 101 and the underlayer 103, the first n-layer 11 is exposed as illustrated in FIG. 18. The exposed surface of the first n-layer 11 corresponds to the first surface 15a of the n-layer 15. The first surface 15a is formed with a rough surface including a plurality of protrusions.

The surface roughness of the first n-layer 11 containing Ge at a greater concentration than the second n-layer 12 tends to be greater than the surface roughness of the second n-layer 12 when the first n-layer 11 is formed on the first substrate 101. Accordingly, the first surface with greater surface roughness than that of the second n-layer 12 is exposed by the removal of the first substrate 101 and the underlayer 103. The first surface 15a corresponds to the main light extraction surface of the light-emitting element. Thus, by the surface of the first n-layer 11 being exposed as the first surface 15a, light extraction efficiency can be improved over a case in which the surface of the second n-layer 12 is exposed as the first surface 15a.

Furthermore, according to the method for manufacturing the light-emitting element according to the second embodiment, after the first surface 15a is exposed, a surface roughening process is performed on the first surface 15a to further increase the surface roughness of the first surface 15a. For example, a CMP method or the like can be used for the surface roughening process. In this case, a second region 15a2 of the first surface 15a is covered by a mask, and the surface roughening process is performed on a first region 15a1 to further increase the surface roughness of the first region 15a1 (or the height of the protrusions of the first region 15a1).

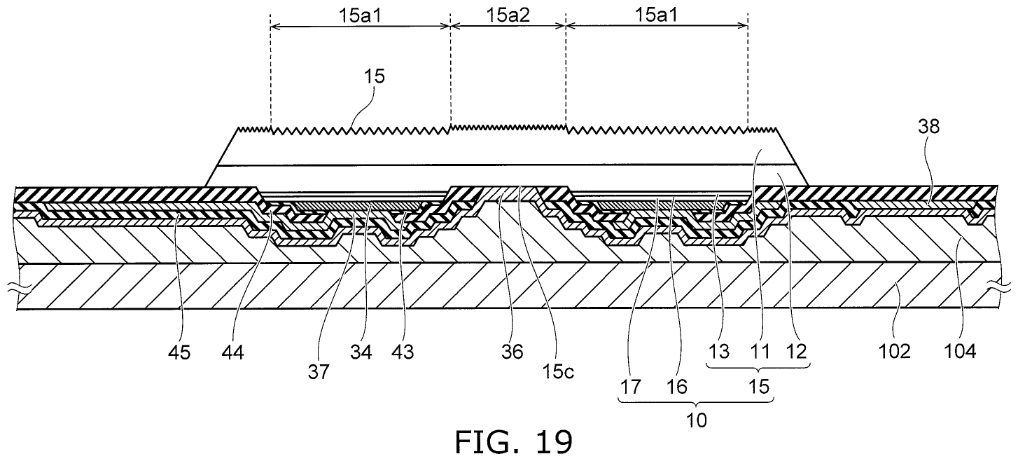

After the first n-layer 11 is exposed, for example, a part of the first n-layer 11 and a part of the second n-layer 12 are removed from a surface where the first n-layer 11 is exposed by the RIE method, and a part of the second insulating film 44 is exposed from the semiconductor structure 10 as illustrated in FIG. 19. Accordingly, the semiconductor structure is separated into a plurality of element portions. Furthermore, the semiconductor structure in the region where the pad electrode described below is to be disposed is also removed.

The active layer 16 and the p-layer 17 are located below the first region 15a1. The connection portion of the n-electrode 36 and the third surface 15c is located below the second region 15a2. In the first region 15a1, a plurality of protrusions with a height greater than that of the protrusions formed in the second region 15a2 are formed by performing a surface roughening process on the first region 15a1. In this manner, the efficiency of extraction of the light from the active layer 16 from the first region 15a1 can be further improved.

Also, by performing a surface roughening process on the first region 15a1, the minimum thickness of the first n-layer 11 below the first region 15a1 is made thinner than the minimum thickness of the first n-layer 11 below the second region 15a2. Accordingly, the attenuation of light at the first n-layer 11 below the first region 15al can be suppressed, and the efficiency of the light extraction from the first region 15a1 can be further improved.

Also, the minimum thickness of the first n-layer 11 below the second region 15a2 is made thicker than the minimum thickness of the first n-layer 11 below the first region 15al. That is, by increasing the thickness of the n-layer 15 where the connection portion of the n-electrode 36 and the third surface 15c is located, the forward voltage can be reduced.

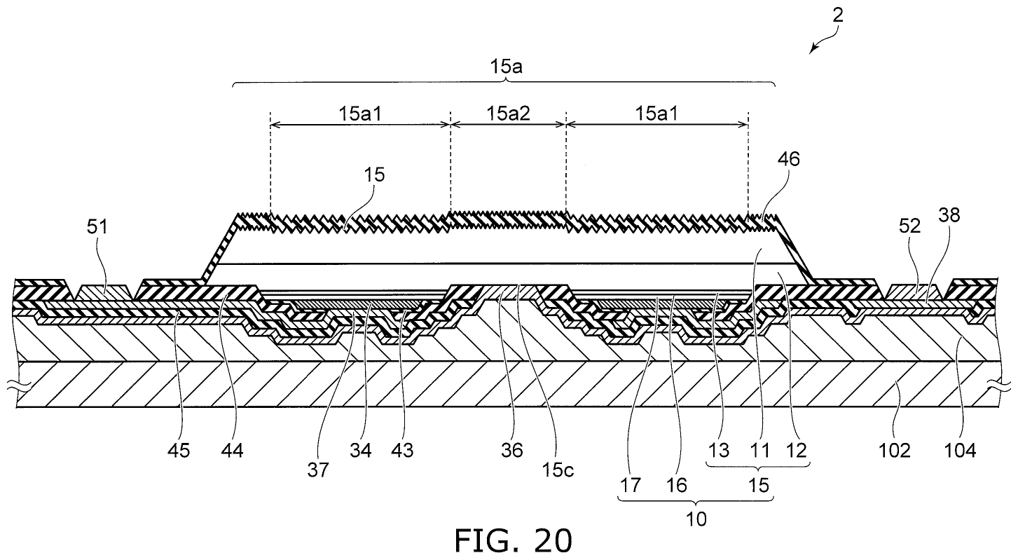

After the process illustrated in FIG. 19, as illustrated in FIG. 20, a protective film 46, a p-pad electrode 51, and an n-pad electrode 52 are formed. Then the second substrate 102 is cut at a predetermined position, and a light-emitting element 2 according to the second embodiment is obtained. The protective film 46 covers the first surface 15a, the lateral surface of the semiconductor structure 10, and the second insulating film 44. SiN, SiO₂, or the like can be used for the protective film 46, for example. After the protective film 46 is formed, a part of the protective film 46 and a part of the second insulating film 44 on the p-electrode 37 in a region where the semiconductor structure 10 is not disposed are removed, and a second p-opening portion exposing the p-electrode 37 is formed. Also, a part of the protective film 46 and a part of the second insulating film 44 on the conductive member 38 in a region where the semiconductor structure 10 is not disposed are removed, and a third n-opening portion exposing the conductive member 38 is formed. Then, the p-pad electrode 51 is disposed in the second p-opening portion, and the n-pad electrode 52 is disposed in the third n-opening portion. The p-pad electrode 51 is electrically connected to the p-electrode 37, and the n-pad electrode 52 is electrically connected to the n-electrode 36 through the conductive member 38.

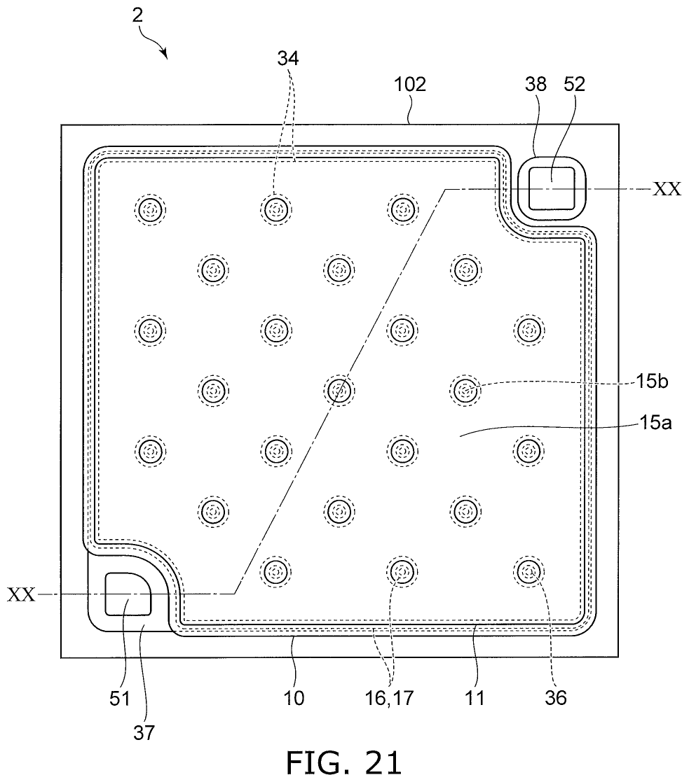

FIG. 21 is a plan view of the light-emitting element 2 according to the second embodiment. FIG. 20 is a cross-sectional view taken along line XX-XX of FIG. 21.

The semiconductor structure 10 of the light-emitting element 2 includes the n-layer 15, the p-layer 17, and the active layer 16 that is disposed between the n-layer 15 and the p-layer 17 and that emits ultraviolet light.

The n-layer 15 includes the first surface 15a where the plurality of protrusions are disposed, the second surface 15b located opposite to the first surface 15a and where the p-layer 17 and the active layer 16 are disposed, and the third surface 15c located opposite to the first surface 15a, exposed from the p-layer 17 and the active layer 16, and where the n-electrode 36 is connected.

The n-layer 15 includes the first n-layer 11, which is an AlGaN layer doped with Ge, and the second n-layer 12, which is an AlGaN layer doped with Si. Also, the n-layer 15 can further include the third n-layer 13, which is an AlGaN layer doped with Si. That is, the p-layer 15 contains Al, Ga, Si, and Ge.

As illustrated in FIG. 20, the upper surface of the first n-layer 11 corresponds to the first surface 15a of the n-layer 15. In the example illustrated in FIG. 20, the first n-layer 11, the second n-layer 12, and the third n-layer 13 are disposed in this order from the first surface of the n-layer 15. The active layer 16 is disposed on a surface of the third n-layer 13 opposite to a surface of the third n-layer 13 facing the second n-layer 12. The third surface that comes into contact with the n-electrode 36 corresponds to a part of the second n-layer 12.

The Ge concentration in a portion proximate to the first surface 15a of the n-layer 15 is greater than the Ge concentration in a portion proximate to the second surface 15b of the p-layer 15 and the Ge concentration in a portion proximate to the third surface 15c of the n-layer 15. The Si concentration in a portion proximate to the third surface 15c of the n-layer 15 is greater than the Si concentration in a portion proximate to the first surface 15a of the n-layer 15. The Si concentration in a portion proximate to the second surface 15b of the n-layer 15 is greater than the Si concentration in a portion proximate to the first surface 15a of the n-layer 15.

The Ge concentration in a portion proximate to the first surface 15a of the n-layer 15 is greater than the Ge concentration in a portion proximate to the second surface 15b of the p-layer 15 and the Ge concentration in a portion proximate to the third surface 15c of the n-layer Thus, as described above, the surface roughness of the first surface 15a is easily made greater than the surface roughness of the second surface 15b and the surface roughness of the third surface 15c, and the extraction efficiency of the light from the first surface 15a can be improved.

The n-electrode 36 connects to the third surface 15c included in a portion of the p-layer 15 with a greater Si concentration than that of a portion of the n-layer 15 proximate to the first surface 15a, and thus forward voltage can be reduced.

The embodiments of the present invention have been described above with reference to specific examples. However, the present invention is not limited to these specific examples. All forms that a person skilled in the art can implement by modifying the design as appropriate based on the above-described embodiments of the present invention are also included in the scope of the present invention, as long as they encompass the spirit of the present invention. In addition, in the spirit of the present invention, a person skilled in the art can conceive of various modified examples and modifications, and those modified examples and modifications will also fall within the scope of the present invention.

### REFERENCE SIGNS LIST

1, 2 Light-emitting element
10 Semiconductor structure
11 First n-layer
12 Second n-layer
13 Third n-layer
15 n-layer
15a First surface
15b Second surface
15c Third surface
16 Active layer
17 p-layer
31 p-electrode
32 n-electrode
33 Back surface electrode
34 Reflective electrode
36 n-electrode
37 p-electrode
38 Conductive member
51 p-pad electrode
52 n-pad electrode
101 First substrate
102 Second substrate
103 Underlayer
104 Joint member

1. A method for manufacturing a light-emitting element comprising:
forming a first n-layer above a first substrate by using a first source gas comprising an Al source gas, a Ga source gas, and a Ge source gas, the first n-layer being made of a nitride semiconductor layer;
forming a second n-layer above the first n-layer by using a second source gas comprising an Al source gas, a Ga source gas, and a Si source gas, the second n-layer being made of a nitride semiconductor layer;
forming an active layer configured to emit ultraviolet light above the second n-layer, the active layer being made of a nitride semiconductor layer;
forming a p-layer above the active layer, the p-layer being made of a nitride semiconductor layer;
forming a p-electrode on the p-layer;
exposing the second n-layer by removing the first substrate and the first n-layer; and
forming an n-electrode on the second n-layer exposed in the step of exposing the second n-layer.

2. The method for manufacturing a light-emitting element according to claim 1, further comprising
after the step of forming the p-electrode, joining the p-electrode and a second substrate by disposing the second substrate at a position proximate to the p-layer, wherein
after the step of joining the p-electrode and the second substrate, the step of exposing the second n-layer is performed.

3. The method for manufacturing a light-emitting element according to claim 1, wherein
in the step of forming the second n-layer, the second n-layer is formed with a thickness greater than a thickness of the first n-layer.

4. The method for manufacturing a light-emitting element according to claim 2, wherein
in the step of forming the second n-layer, the second n-layer is formed with a thickness greater than a thickness of the first n-layer.

5. The method for manufacturing a light-emitting element according to claim 1, wherein
in the step of forming the first n-layer, the first n-layer is formed with a thickness in a range from 0.2 μm to 1.2 μm.

6. The method for manufacturing a light-emitting element according to claim 2, wherein
in the step of forming the first n-layer, the first n-layer is formed with a thickness in a range from 0.2 μm to 1.2 μm.

7. The method for manufacturing a light-emitting element according to claim 1, wherein
in the step of forming the second n-layer, the second n-layer is formed with a thickness in a range from 1 μm to 3 μm.

8. The method for manufacturing a light-emitting element according to claim 2, wherein
in the step of forming the second n-layer, the second n-layer is formed with a thickness in a range from 1 μm to 3 μm.

9. A method for manufacturing a light-emitting element comprising:
forming a first n-layer above a first substrate by using a first source gas comprising an Al source gas, a Ga source gas, and a Ge source gas, the first n-layer being made of a nitride semiconductor layer;
forming a second n-layer above the first n-layer by using a second source gas comprising an Al source gas, a Ga source gas, and a Si source gas, the second n-layer being made of a nitride semiconductor layer;
forming an active layer configured to emit ultraviolet light above the second n-layer, the active layer being made of a nitride semiconductor layer;
forming a p-layer above the active layer, the p-layer being made of a nitride semiconductor layer;
exposing a part of the second n-layer from the p-layer and the active layer by removing a part of the p-layer and a part of the active layer from a surface where the p-layer is exposed;
forming an n-electrode on the part of the second n-layer;
forming a p-electrode on the p-layer; and
exposing the first n-layer by removing the first substrate.

10. The method for manufacturing a light-emitting element according to claim 9, further comprising
after the step of forming the n-electrode and the step of forming the p-electrode, disposing a second substrate at a position proximate to the n-electrode and the p-electrode, wherein
after the step of disposing the second substrate, the step of exposing the first n-layer is performed.

11. The method for manufacturing a light-emitting element according to claim 9, wherein
in the step of forming the second n-layer, the second n-layer is formed with a thickness greater than a thickness of the first n-layer.

12. The method for manufacturing a light-emitting element according to claim 10, wherein
in the step of forming the second n-layer, the second n-layer is formed with a thickness greater than a thickness of the first n-layer.

13. The method for manufacturing a light-emitting element according to claim 9, wherein
in the step of forming the first n-layer, the first n-layer is formed with a thickness in a range from 0.2 μm to 1.2 μm.

14. The method for manufacturing a light-emitting element according to claim 10, wherein
in the step of forming the first n-layer, the first n-layer is formed with a thickness in a range from 0.2 μm to 1.2 μm.

15. The method for manufacturing a light-emitting element according to claim 9, wherein
in the step of forming the second n-layer, the second n-layer is formed with a thickness in a range from 1 μm to 3 μm.

16. The method for manufacturing a light-emitting element according to claim 10, wherein
in the step of forming the second n-layer, the second n-layer is formed with a thickness in a range from 1 μm to 3 μm.

17. A light-emitting element comprising:
a semiconductor structure made of a nitride semiconductor layer and comprising an n-layer, a p-layer, and an active layer configured to emit ultraviolet light and disposed between the n-layer and the p-layer;
an n-electrode disposed on the n-layer and electrically connected to the n-layer; and
a p-electrode disposed on the p-layer and electrically connected to the p-layer, wherein
the n-layer contains Al, Ga, Si, and Ge,
the n-layer comprises a first surface where a plurality of protrusions are disposed, a second surface located opposite to the first surface and where the p-layer and the active layer are disposed, and a third surface located opposite to the first surface, exposed from the p-layer and the active layer, and where the n-electrode is connected,
a Ge concentration in a portion proximate to the first surface of the n-layer is greater than a Ge concentration in a portion proximate to the second surface and the third surface of the n-layer, and
a Si concentration in a portion proximate to the third surface of the n-layer is greater than a Si concentration in a portion proximate to the first surface of the n-layer.
